(19) United States
(12) Patent Application Publication
(10) Pub. No.: US 2005/0189551 A1
(43) Pub. Date: Sep. 1, 2005

(54) High power and high brightness white LED assemblies and method for mass production of the same

(76) Inventors: Hui Peng, Fremont, CA (US); Gang Grant Peng, Fremont, CA (US)

Correspondence Address: Hui Peng, 35964 Vivian Place, Fremont, CA, 94536, US

(21) Appl. No.: 10/787,816

(22) Filed: Feb. 26, 2004

(51) Int. Cl. H01L 33/00

(52) U.S. Cl. 257/94

(57) ABSTRACT

High power and high brightness light emitting diode (LED) assemblies emitting white light are disclosed. The present invention also discloses methods for cost effective mass production of the high power and high brightness LED assemblies with high throughput.

### BACKGROUND OF THE INVENTION

(1) Field of the Invention

The present invention relates to high power and high brightness white light emitting diode (LED) assemblies and method for mass production of the same.

(2) Prior Art

Extensive efforts have been devoted to develop white LEDs and white LED assemblies by: (1) using wavelength converter materials including fluorescent materials, photon-recycling semiconductors, and dye, patents for this method include U.S. Pat. No. 6,635,987 by Wojnarowski, et al, U.S. Pat. No. 6,642,618 by Yagi, et al; (2) integrating red, green, and blue LEDs (RGB LEDs) into a LED lamp; (3) growing more than one epitaxial layers emitting lights of different wavelengths on the same substrate, patents for this method include U.S. Pat. No. 6,163,038 by Chen, et al.; and (4) stacking two LED chips of different wavelengths, patents include U.S. Pat. No. 6,633,120 by Salam.

There are drawbacks for the above mentioned white LEDs: (1) The life time of fluorescent materials is not as long as that of LEDs; (2) The control system for RGB LEDs is complicated and expensive; (3) White LEDs manufactured by growing two or more epitaxial layers of different wavelengths on a substrate do not have high brightness comparing with the existing LEDs of blue and other colors, the growing process is complicated, and the requirement of lattice match limits the selections of material systems for the epitaxial layers; and (4) The stacking two LED chips emitting lights of different wavelengths to manufacturing high brightness white LEDs is an economic way. Salam disclosed white LED assemblies and each comprises two LED chips of different wavelengths stacked to each other. As shown in FIG. 1, the drawbacks of Salam's white LED assemblies are the following: (a) LED 110 and LED 120 are bonded at chip level; (b) wire bonding pads are on both sides of the LED assemblies; (c) two LEDs are either skewed or shifted one relative to the other for wire bonding, thus wasting the material of the active layers and lower the output light intensity. Therefore the mass production for Salam's stacking white LED assemblies is difficult and expensive, throughput and yield are very low.

Therefore there is a need for new high brightness and high power white LED assemblies and for methods of mass production to provide high power, high efficiency, high brightness, and economic white LED assemblies.

### BRIEF SUMMARY OF THE INVENTION

In the present invention, new high brightness high power white LED assemblies and method of manufacturing the same are disclosed.

The high brightness white LED assemblies of the present invention comprise a first epitaxial layer emitting a light of a first wavelength which is disposed on an electrically conductive submount, a second epitaxial layer emitting a light of a second wavelength disposed on the first epitaxial layer, and an electrode connected to the exposed surface of the second epitaxial layer.

The most bright commercially available LEDs of different colors are always selected for manufacturing the high brightness white LED assemblies of the present invention, therefore, the high brightness white LED assemblies of the present invention provide brighter white light.

One of embodiments of the high brightness white LED assemblies of the present invention comprises a second epitaxial layer which is a blue GaN epitaxial layer grown on a sapphire substrate which is then removed, and a first epitaxial layer is a yellow AlGaInP epitaxial layer grown on a GaAs or GaP substrate which is then removed.

Some embodiments of the high brightness white LED assemblies of the present invention have two electrodes, one is contacted to the second epitaxial layer, the other is the bottom side of the submount which is electrically connected to the first epitaxial layer, i.e., two epitaxial layers are electrically connected in serial. There is only one wire bonding pad needed.

Some embodiments of the high brightness white LED assemblies of the present invention have three electrodes, the second and the first electrodes having the same polarity are electrically connected to the second epitaxial layer and the bottom side of the submount respectively, the third electrode having opposite polarity is sandwiched between the first epitaxial layer and the second epitaxial layer, i.e., the two LED chips are electrically controlled separately, so the colors of the output lights emitted by two epitaxial layers may be controlled to certain degree. In this embodiment, there are two wire bonding pads on the same side of the high brightness white LED assemblies.

Some of embodiments of the present invention have two active layers directly bonded to each others, therefore two epitaxial layers are grown for a shorter time to lower production cost.

The high brightness high power white LED assemblies of the present invention have the following advantages.
1. Always select commercially available most bright and high power monochromatic LEDs to manufacture white LED assemblies, thus the provided white light is brighter.
2. The bonding process of the high brightness white LED assemblies are at the wafer level, instead of at the chip level, so the mass production is practical.
3. Since either the two wire bonding pads are on the same side of the high brightness white LED assemblies or there is only one wire bonding pad, the manufacture process of wire bonding is much easier and throughput and yield are much higher.
4. The high brightness white LED assemblies of the present invention have all of the advantages of flip chip technique, such as fast heat dissipation.
5. Since there is less wire bonding area comparing to prior art and two LED chips are not skewed or shifted one relative to the other, the material of the active layers is utilized to maximum.
6. The second epitaxial layer is exposed, the second electrode may be so patterned and arranged that to reduce the current crowding effect, fully utilize the material of active layer, and distribute the current more evenly.
7. The current density may be higher, thus the high brightness white LEDs are brighter.
8. For one of embodiments, GaN LEDs as the second epitaxial layer, the sapphire substrate has been removed at wafer level, so the cost of the wafer dicing process is much lower.
9. For a lamp of the high brightness white LED assemblies, after removing the substrate the second epitaxial layer grown on, the second epitaxial layer is directly exposed to a dome material that covers the high brightness white LED assemblies and has the same refractive index as that of the second epitaxial layer, which results in eliminating totally internal reflections when light incidents from the second epitaxial layer to the substrate which has lower refractive index and from the substrate to the dome material.
10. The shape and diameter of the dome is so determined that there is no totally internal reflection when light incidents from the dome to air. Therefore there is no light trapped in the dome for the high brightness white LED assemblies of the present invention.
11. The high power and high brightness LED assemblies and methods for mass production of the same of the present invention may be applied to other LED assemblies emitting light of any desired mixing colors.

The primary object of the present invention is to provide new LED assemblies for providing high brightness high power white light and to have fast thermal dissipation, higher light extraction efficiency, reduced current crowding effect, and higher current density.

The second object of the present invention is to provide new methods for cost effective mass production of the high brightness high power white LED assemblies with high throughput.

The third object of the present invention is to provide new high brightness high power white LED assemblies and lamps to significantly improve the extraction efficiency by eliminating the totally internal reflection.

The fourth object of the present invention is to provide high brightness high power white LED assemblies to eliminate the lattice mismatch to improve the internal efficiency.

Further objects and advantages of the present invention will become apparent from a consideration of the ensuing description and drawings.

### BRIEF DESCRIPTION OF THE SEVERAL VIEWS OF DRAWINGS

The novel features believed characteristic of the present invention are set forth in the claims. The invention itself, as well as other features and advantages thereof will be best understood by referring to detailed descriptions that follow, when read in conjunction with the accompanying drawings.

FIGS. 1a and 1b are top and cross sectional views of prior art.

FIGS. 2a and 2b are cross sectional views of white LED assemblies of the present invention with one wire bonding pad.

FIGS. 3a and 3b are cross sectional views of white LED assemblies of the present invention with two wire bonding pads.

FIGS. 4a and 4b are cross sectional views of white LED assemblies of the present invention with two active layers directly bonded and having one wire bonding pad.

FIGS. 5a and 5b are cross sectional views of white LED assemblies of the present invention with two active layers directly bonded and having two wire bonding pads.

FIGS. 6a and 6b are cross sectional view of white LED assemblies of the present invention with MQBW and one wire bonding pad.

FIGS. 7a and 7b are cross sectional view of white LED assemblies of the present invention with MQBW and two wire bonding pads.

FIGS. 8a and 8b are flow charts of manufacturing white LED assemblies of the present invention with one and two wire bonding pads respectively.

FIGS. 9a to 9d are top views of different patterned electrodes on the exposed second epitaxial layer with one or two wire bonding pads.

FIG. 10 is a sectional view of LED lamp of prior art.

FIGS. 11a and 11b are sectional views of two high brightness white LED lamps with high extraction efficiency.

### DETAILED DESCRIPTION OF THE INVENTION

While embodiments of the present invention will be described below, those skilled in the art will recognize that other LED assemblies, LED lamps and mass production processes are capable of implementing the principles of the present invention. Thus the following description is illustrative only and not limiting.

Reference is specifically made to the drawings wherein like numbers are used to designate like members throughout.

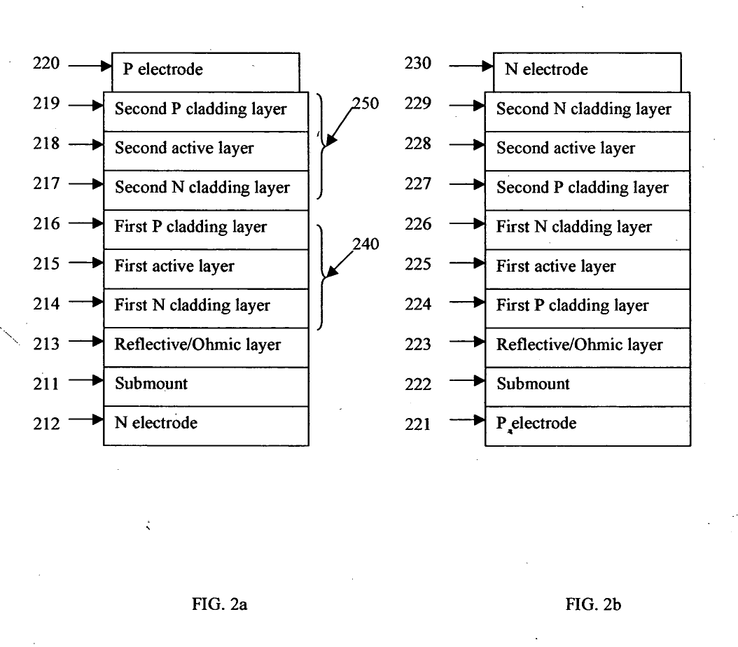

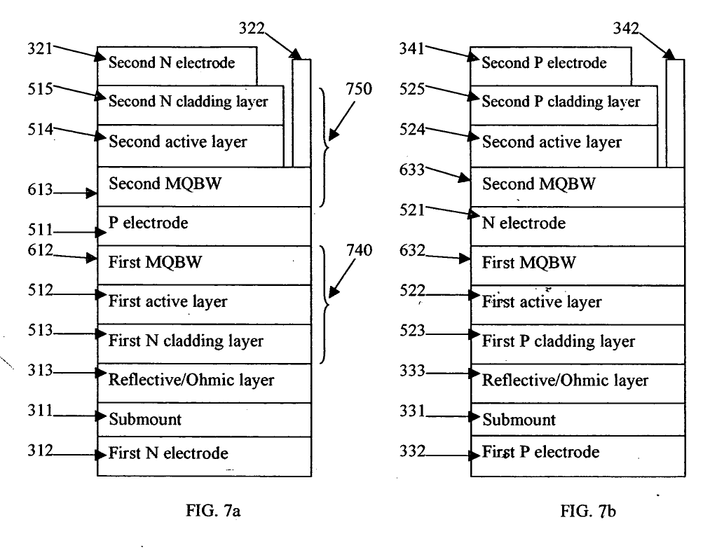

Note the followings that are applied to all of embodiments of high brightness high power white LED assemblies of the present invention:
(1) The dimensions of all of drawings are not to scale.
(2) The intensities and wavelengths of two LED epitaxial wafers are selected, according to the chromaticity diagram, so that two mixed lights provide desired color.
(3) Material systems of a first epitaxial layer of a first LED epitaxial wafer emitting light of longer wavelength are selected from a group comprising: AlGaInP, InGaN, GaInNP, GaNP, InGaP, GaP:N, AlInP, AlGaAs, and GaAsP.
(4) Material systems of a second epitaxial layer of a second LED epitaxial wafer emitting light of shorter wavelength are selected from a group comprising: GaInN, AlGaInN, GaN, BeZnCdSe, BeZnCdTe, ZnSe, ZnCdSe, and ZnSeTe.
(5) The material systems of multiple quantum barrier-well (MQBW) layers are determined by the material systems of the first and second epitaxial layers respectively. The multiple quantum barrier layers and multiple quantum well layers are laminated alternately and cyclically.
(6) A submount for the LED assemblies is selected from a group comprising electrically conductive Si, SiC, and thin films of Cu and Al. The submounts have high thermal conductivity for fast heat dissipation.
(7) Materials for a reflective/Ohmic layer sandwiched between a submount and the first epitaxial layer are selected from agroup comprising Ag, Al, Au, In, Ni, Ti, Pd, Pt, and alloys of above metals.
(8) A first electrode on the bottom side of the submount comprises Au/Sn.
(9) Electrodes sandwiched between first and second epitaxial layers or between first and second MQBW layers are transparent for, at least, light of longer wavelength.
(10) Electrodes of different polarities are electrically isolated.
(11) The first epitaxial layer is always bonded to the submount, a second epitaxial layer is stacked on the top of the first epitaxial layer. The second epitaxial layer is transparent for light of longer wavelength.
(12) To bond two epitaxial layers, conductive epoxy, a thin layer of Indium, ITO, and other eutectic materials may be employed. Bonding layers are transparent for, at least, longer wavelength light emitted by the first epitaxial layer.
(13) The LED assemblies in FIGS. 2a and 2b, FIGS. 3a and 3b, FIGS. 4a and 4b, FIGS. 5a and 5b, FIGS. 6a and 6b, and FIGS. 7a and 7b have the same structure respectively, except that N and P are switched. Therefore only FIG. 2a, FIG, 3a, FIG, 4a, FIG, 5a, FIG, 6a, and FIG. 7a are described in detail below.

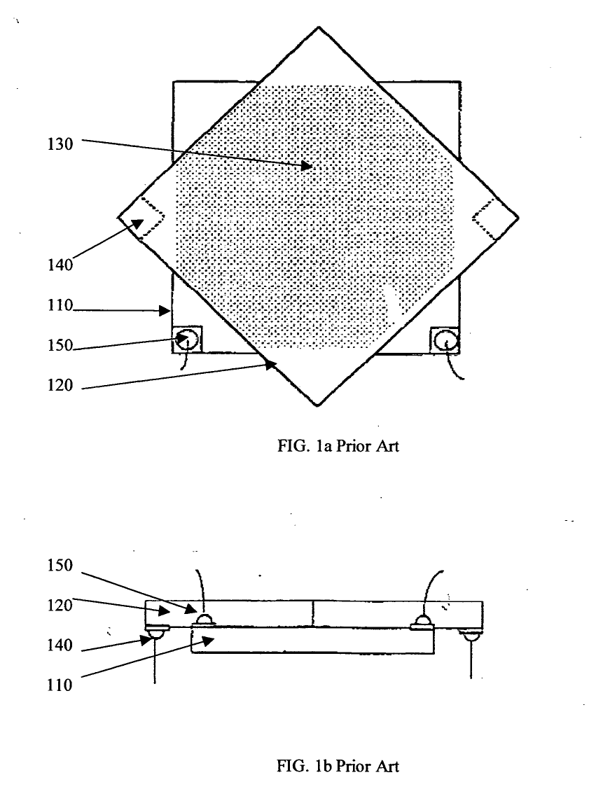

FIGS. 1a and 1b show a prior art of two LEDs of different wavelengths stacked to each other. LED 110 and LED 120 are bonded together at chip level. Only octagonal overlap area 130 emitting lights. There are two of wire bonding pad 150 on LED 110 and two of wire bonding pad 140 on LED 120. Normal size for wire bonding pad is about 100×100 micrometer, therefore significant material of active areas of LED 110 and LED 120 is wasted. Also as shown in FIG. 1b, wire bonding pad 140 and 150 are on different sides of LED assembly, therefore the wire bonding process is very difficult and time consuming.

FIG. 2a shows an embodiment of the present invention. Reflective/Ohmic layer 213 and N electrode 212 are respectively disposed on submount 211 that is electrically conductive. First epitaxial layer 240 comprising first N-type cladding layer 214, first P-type cladding layer 216, and first active layer 215 sandwiched between first N-type cladding layer 214 and first P-type cladding layer 216, is disposed on reflective/Ohmic layer 213. Second epitaxial layer 250 comprising second N-type cladding layer 217, second P-type cladding layer 219, and second active layer 218 sandwiched between second N-type cladding layer 217 and second P-type cladding layer 219, is disposed on first epitaxial layer 240. P electrode 220 is disposed on second P-type cladding layer 219. N electrode 212 is the conductive layer disposed on submount 211. First and second epitaxial layer 240 and 250 are electrically connected in serial.

In this embodiment only one wire bonding pad is needed.

This embodiment allows controlling the color of mixed lights to some degree by choosing the intensities and wavelengths of lights emitted by first and second epitaxial layer 240 and 250 respectively.

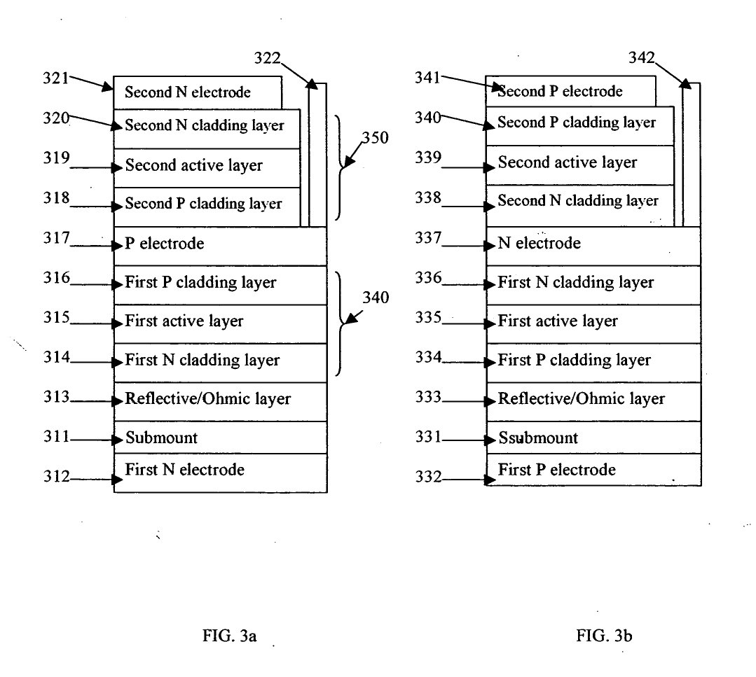

FIG. 3a shows first and second epitaxial layer 340 and 350 are electrically controlled separately. Reflective/Ohmic layer 313 and first N electrode 312 are respectively disposed on submount 311 that is electrically and thermally conductive to improve thermal dissipation. First epitaxial layer 340 comprising first N-type cladding layer 314, first P-type cladding layer 316, and first active layer 315 sandwiched between first N-type cladding layer 314 and first P-type cladding layer 316, is disposed on reflective/Ohmic layer 313. Second epitaxial layer 350 comprising second N-type cladding layer 320, second P-type cladding layer 318, and second active layer 319 sandwiched between second N-type cladding layer 320 and second P-type cladding layer 318, is disposed on first epitaxial layer 340. Second N electrode 321 is disposed on second N-type cladding layer 320. First N electrode 312 is a conductive layer disposed on submount 311. P electrode 317 is sandwiched between first P-type cladding layer 316 and second P-type cladding layer 318. A pre-determined area of second epitaxial layer 350 is etched down until P electrode 317 is exposed. Then P contact pad 322 is disposed on P electrode 317. First and second epitaxial layer 340 and 350 are electrically controlled separately.

For this embodiment, there are two wire bonding pads, second N electrode 321 and P contact pad 322, on the same side of the white LED assemblies and easier to wire bonding.

This embodiment provides additional controls on the color of mixed lights of the white LED assemblies by controlling the applied voltages and currents to first and second epitaxial layers respectively.

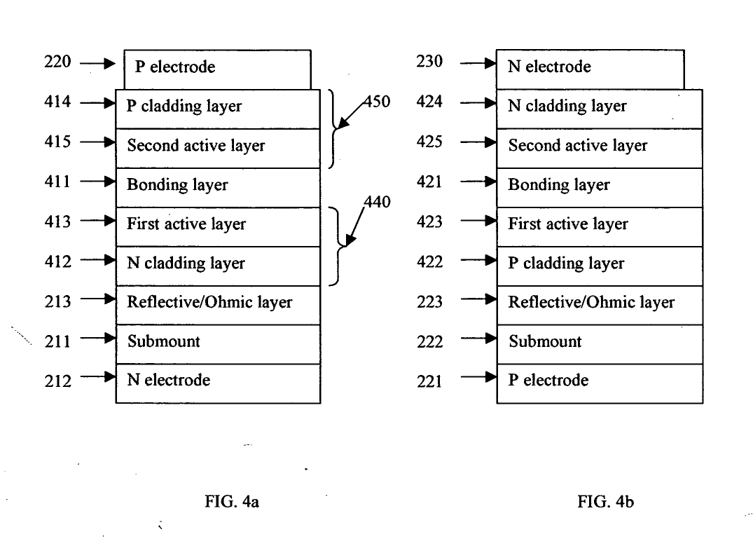

FIG. 4a shows an economic way for manufacturing white LED assemblies. Reflective/Ohmic layer 213 and N electrode 212 are respectively disposed on submount 211. First epitaxial layer 440 comprising N-type cladding layer 412 and first active layer 413, is disposed on reflective/Ohmic layer 213. Second epitaxial layer 450 comprising P-type cladding layer 414 and second active layer 415, is disposed on bonding layer 411 that is disposed on first epitaxial layer 440. Bonding layer 411 may be conductive epoxy or a layer of either an adhesive metal or alloy comprising Indium. Bonding layer 411 is so thin that it is transparent for light. P electrode 220 is disposed on P-type cladding layer 414. N electrode 212 is the conductive layer disposed on submount 211. First and second epitaxial layer 440 and 450 are electrically connected in serial.

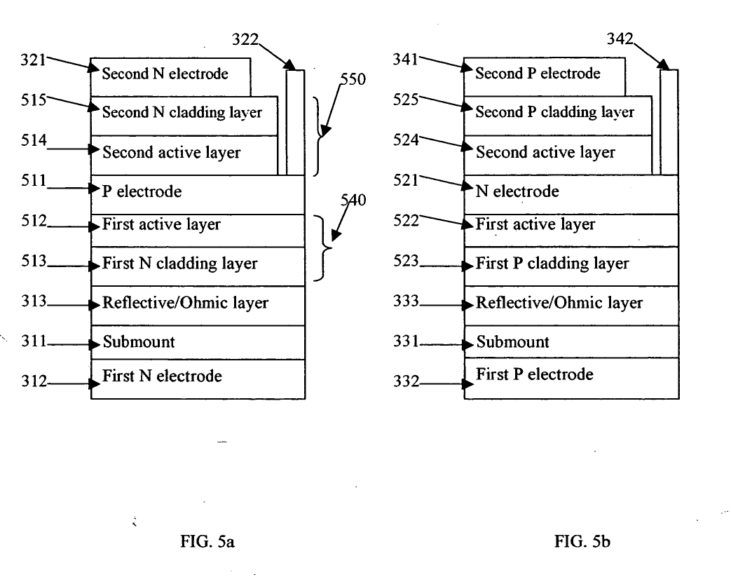

FIG. 5a shows another economic way for manufacturing white LED assemblies with more control on the color of mixing lights. Reflective/Ohmic layer 313 and first N electrode 312 are respectively disposed on submount 311. First epitaxial layer 540 comprising first N-type cladding layer 513 and first active layer 512, is disposed on reflective/Ohmic layer 313. Second epitaxial layer 550 comprises second N-type cladding layer 515 and second active layer 514. P electrode 511 is sandwiched between first active layer 512 and second active layer 514. Second N electrode 321 is disposed on second epitaxial layer 550. A pre-determined area of second epitaxial layer 550 is etched down until P electrode 511 is exposed. Then P contact pad 322 is disposed on P electrode 511. First and second epitaxial layer 540 and 550 are electrically controlled separately.

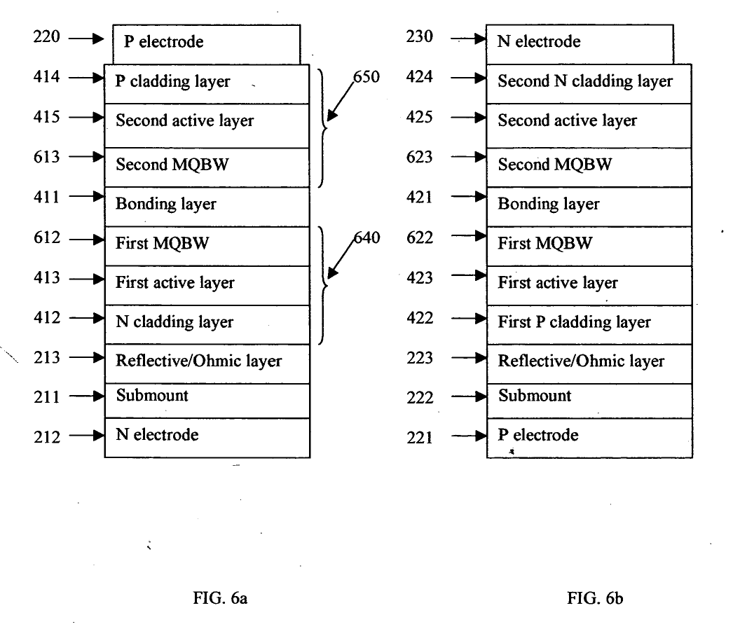

FIG. 6a shows a similar white LED assemblies as that of FIG. 4a, except the following. First epitaxial layer 640 comprises N cladding layer 412, first active layer 413, and first multiple quantum barrier-well (MQBW) layer 612. Second epitaxial layer 650 comprises P cladding layer 414, second active layer 415, and second MQBW layer 613. First and second MQBW layer 612 and 613 are bonded by bonding layer 411. First and second MQBW layer 612 and 613 are grown on first and second active layer 413 and 415 respectively during wafer growth process and for improving the performance.

FIG. 7a shows a similar white LED assemblies as that of FIG. 5a, except additional MQBW. First epitaxial layer 740 comprises first N-type cladding layer 513, first active layer 512, and first MQW 612. Second epitaxial layer 750 comprises second N-type cladding layer 515, second active layer 514, and second MQW 613. Second N electrode 321 is disposed on second epitaxial layer 750. First and second epitaxial layer 740 and 750 are electrically controlled separately. P electrode 511 is sandwiched between first MQBW 612 and second MQBW 613. A pre-determined area of second epitaxial layer 750 is etched down until P electrode 511 is exposed. Then P contact pad 322 is disposed on P electrode 511.

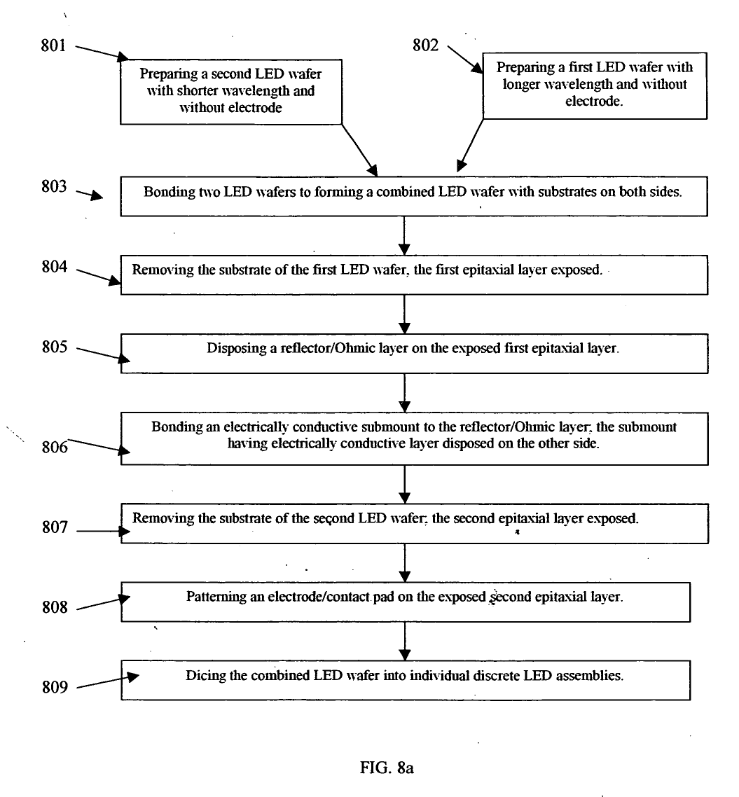

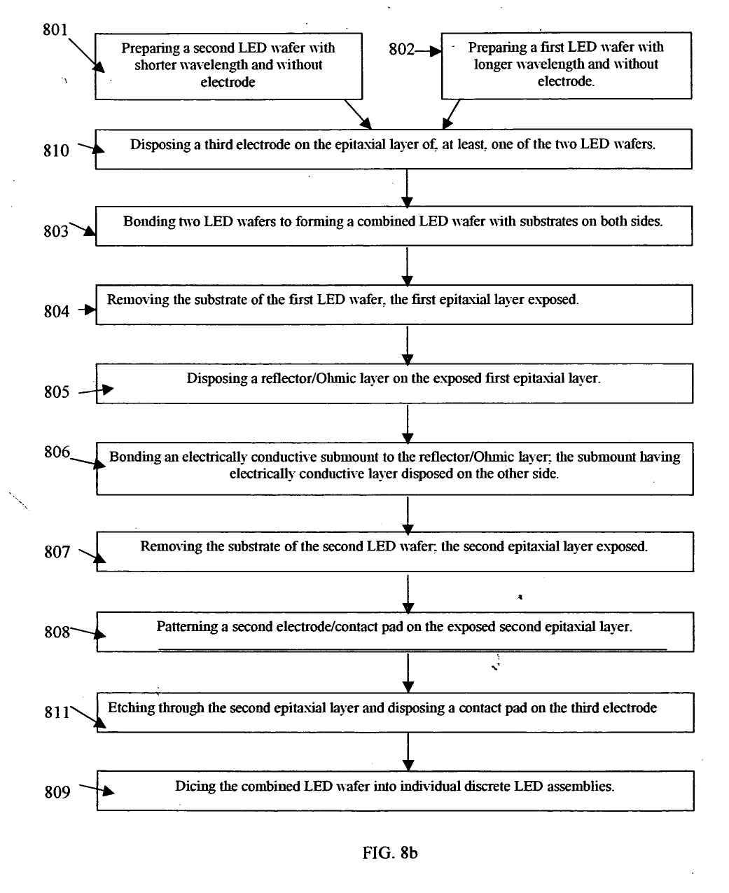

FIGS. 8a and 8b are two slightly different flow charts of manufacturing different embodiments of high brightness high power white LED assemblies.

Process step 801 and 802 are, according to the complementary wavelengths and power ratio, preparing/selecting two LED epitaxial wafers with shorter and longer wavelengths respectively. The preparation of LED epitaxial wafers also needs to take into account methods of removing substrates, since different removing methods require different epitaxial layer growth processes. Embodiments of white LED assemblies of FIGS. 2 and 3 are conventional LEDs and only need to consider requirements on wavelength and power ratio. For embodiments of white LED assemblies of FIG. 4, a epitaxial layer grown on a substrate comprises one type cladding layer and an active layer, the complementary epitaxial layer grown on another substrate comprises the other type cladding layer and an active layer. For embodiments of white LED assemblies of FIG. 5, a epitaxial layer grown on a substrate comprises one type cladding layer and an active layer, the complementary epitaxial layer grown on another substrate comprises the same type cladding layer and an active layer. For embodiments of white LED assemblies of FIG. 6, a epitaxial layer grown on a substrate comprises one type cladding layer, an active layer, and a multiple quantum barrier-well (MQBW) layer, the complementary epitaxial layer grown on another substrate comprises the other type cladding layer, an active layer, and a MQBW layer. For embodiments of white LED assemblies of FIG. 7, a epitaxial layer grown on a substrate comprises one type cladding layer, an active layer, and a MQW layer, the complementary epitaxial layer grown on another substrate comprises the same type cladding layer, an active layer, and a MQW layer.

The rest of the process steps are self-explanatory, listed below.

Step 803, bonding two selected LED epitaxial wafers to form a combined LED epitaxial wafer.

Step 804, removing the substrate of the longer wavelength LED wafer by selective etching, mechanical lapping/polishing, or combination of both. Then the first epitaxial layer of longer wavelength is exposed.

Step 805, coating a reflective/Ohmic layer to the exposed first epitaxial layer.

Step 806, bonding an electrically conductive submount with high thermal conductivity to the reflective/Ohmic layer.

Step 807, removing the substrate of the shorter wavelength LED wafer. For an embodiment of the present invention, the substrate is sapphire which may be removed by mechanical lapping/polishing or laser melting. Then the second epitaxial layer of shorter wavelength is exposed.

Step 808, disposing and/or patterning an electrode/contact pad on the exposed second epitaxial layer.

Step 809, dicing the combined LED epitaxial wafer into individual discrete LED assemblies.

Step 810 of FIG. 8b, disposing a third electrode on, at least, one of the LED epitaxial layers of the LED epitaxial wafers before step 803.

Step 811 of FIG. 8b, disposing a contact pad on the third electrode by first etching through the second epitaxial layer before step 809.

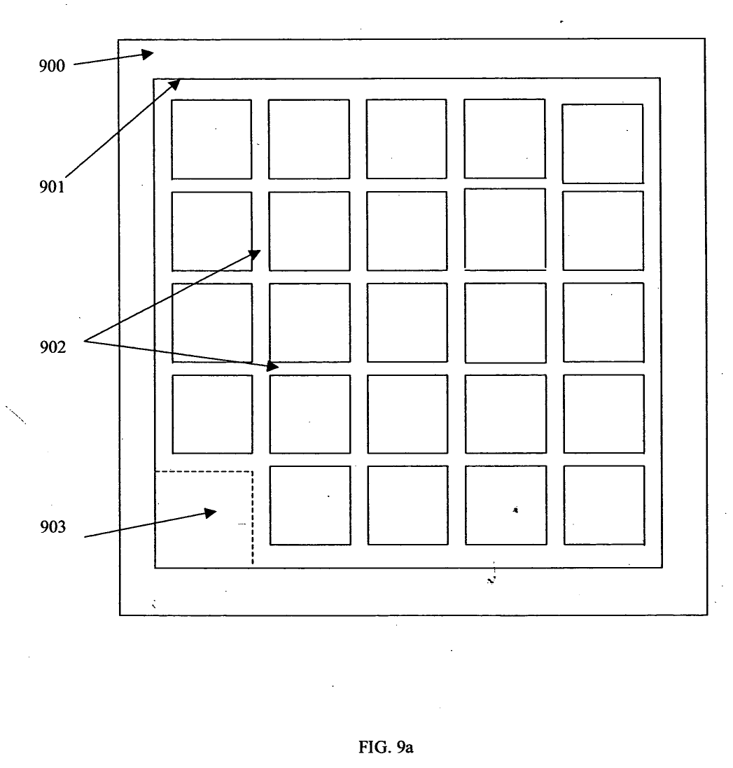

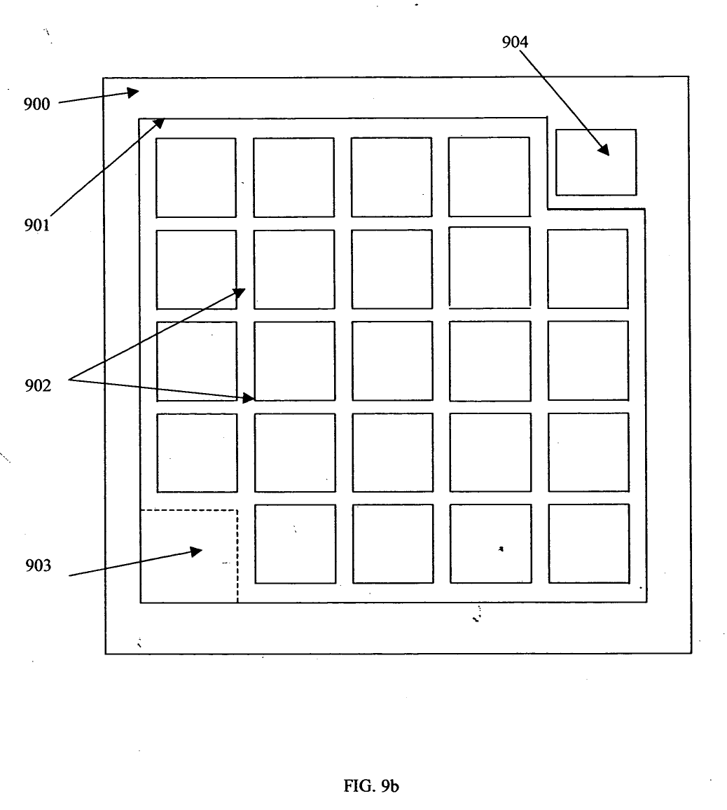

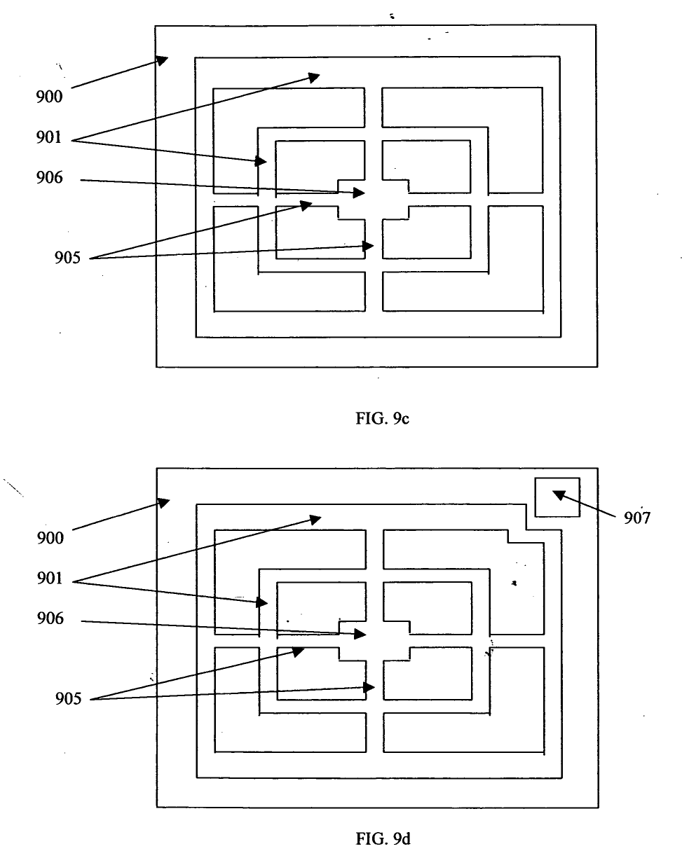

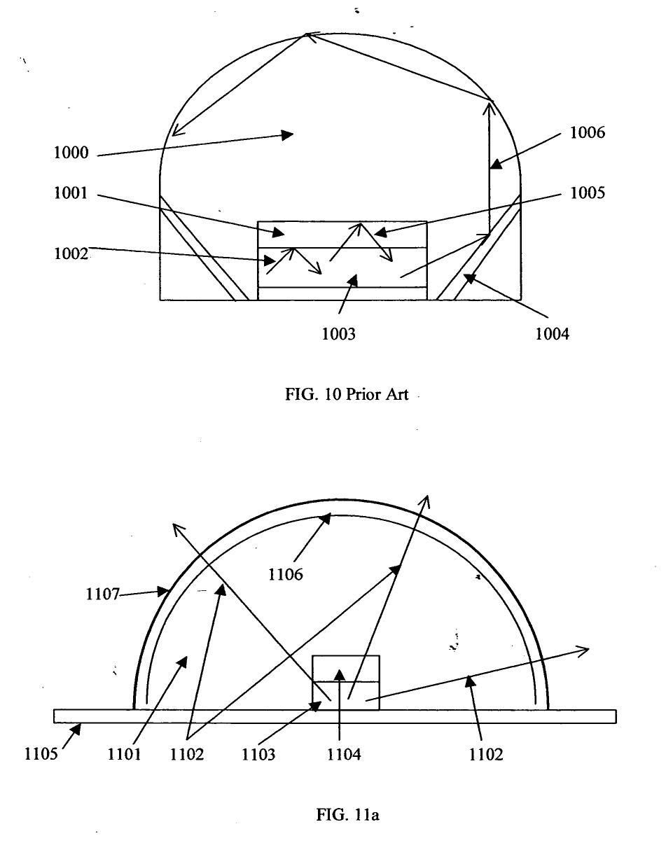

FIGS. 9a and 9b show an embodiment of a patterned electrode having ring-grid-shape and disposed on second epitaxial layer 900. The patterned electrode comprises ring 901, grid 902, and wire bonding pad 903, which are electrically connected. Ring 901 and grid 902 evenly spread the current introduced by wire bonding pad 903 through second epitaxial layer 900 of white LED assembly. FIG. 9b shows a second wire bonding pad 904 which is contacted with P electrode 317 of FIG. 3a, P electrode 511 of FIG. 5a and FIG. 7a.

FIGS. 9c and 9d show an embodiment of patterned electrodes having plus-multi-ring-shape and disposed on second epitaxial layer 900. The patterned electrode comprises a plurality of ring 901, plus 905, and wire bonding pad 906, which are electrically connected. The plurality of ring 901 and plus 905 evenly spread the current introduced by wire bonding pad 906 through second epitaxial layer 900 of white LED assembly. FIG. 9d shows a second wire bonding pad 907 which is contacted with P electrode 317 of FIG. 3a, P electrode 511 of FIG. 5a and FIG. 7a.

FIG. 10 shows a LED lamp of prior art. Light 1002 and light 1005 emitted from active layer 1003 are respectively reflected back by the interfaces between active layer 1003 and transparent substrate 1001 and the interface between substrate 1001 and dome material 1000. Light 1006 is totally reflected back by the interface between dome material 1000 and air.

Note that a conventional LED lamp has a reflective cup 1004 surrounded by dome material, therefore, there are 3 types of totally internal reflections at interfaces: between active layer and substrate, between substrate and dome, and between dome and air, therefore the light extraction efficiency is low.

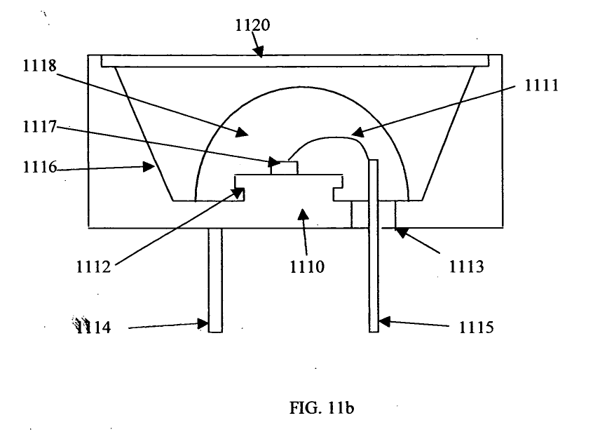

FIG. 11a is an embodiment of a lamp of white LED assemblies of the present invention. A LED assembly of the present invention comprises epitaxial layer 1104 and active layer 1103 attached on base 1105. Dome material 1001 covers the LED assembly. Anti-reflection coating 1107 is coated on surface 1106 of dome material 1101. Epitaxial layer 1104 and active layer 1103 have either the same or similar refractive index, therefore there is no totally internal reflection at the interface between the two. Epitaxial layer 1104 and dome material 1101 doped with nano-particles have either the same or similar refractive index, therefore, the totally internal reflection at the interface between epitaxial layer 1104 and dome material 1101 is eliminated.

From Snell's law, it can be shown that when
R≧nd,
where, R is the diameter of hemisphere-shaped dome, n is the refractive index of dome material, and d is the size of the LED, there is no totally internal reflection at the interface between dome and air. Therefore it is easily to eliminate the totally internal reflection between dome and air by employing large enough hemisphere shaped dome.

Therefore all of three types of the totally internal reflections are completely eliminated.

FIG. 11b is a lamp for white LED assemblies. Transparent cover 1120 seals the lamp. White LED assembly 1117 is disposed on heat sink 1110 which has a neck portion 1112 for holding dome 1118. Pole 1114 is electrically connected with the LED. Wire bonding 1111 connects LED 1117 to pole 1115 which is through hole 1113. Cover 1120 sits on reflective cup 1116 which directs emitted light to the desired direction.

Although the description above contains many specifications and embodiments, these should not be construed as limiting the scope of the present invention but as merely providing illustrations of some of the presently preferred embodiments of the present invention.

Therefore the scope of the present invention should be determined by the claims and their legal equivalents, rather than by the examples given.

1. A light emitting diode (LED) assembly emitting light of mixing colors, comprising:
a first epitaxial layer comprising a first N-type cladding layer, a first P-type cladding layer, and a first active layer sandwiched between said first N-type and said first P-type cladding layers, and emitting light of first wavelength;
a second epitaxial layer comprising a second N-type cladding layer, a second P-type cladding layer, and a second active layer sandwiched between said second N-type and said second P-type cladding layers, and emitting light of second wavelength; wherein one side of said second epitaxial layer bonding to one side of said first epitaxial layer;
a second electrode for wire bonding disposed on the other side of said second epitaxial layer;
a submount that is electrically conductive; wherein one side of said submount bonding to the other side of said first epitaxial layer.

2. The light emitting diode (LED) assembly emitting light of mixing colors of claim 1,
further comprises a first electrode disposed on the other side of said submount.

3. The light emitting diode (LED) assembly emitting light of mixing colors of claim 2,
wherein said first electrode has the opposite polarity to that of said second electrode so that said first epitaxial layer and said second epitaxial layer are electrically connected in serial.

4. The light emitting diode (LED) assembly emitting light of mixing colors of claim 2,
further comprises a third electrode; wherein said second electrode having the same polarity as that of said first electrode; and wherein said third electrode having the opposite polarity to that of said first and said second electrodes so that said first epitaxial layer and said second epitaxial layer are electrically controlled separately.

5. The light emitting diode (LED) assemblies emitting light of mixing colors of claim 1,
further comprising a reflector/Ohmic layer sandwiched between said submount and said first epitaxial layer.

6. The light emitting diode (LED) assembly emitting light of mixing colors of claim 5,
wherein said reflector/Ohmic layer comprises metals selected from a group comprising Al, Au, Ag, In, Ni, Ti, Pd, Pt, and alloys of said metals.

7. The light emitting diode (LED) assembly emitting light of mixing colors of claim 1,
wherein said second electrode for wire bonding is patterned for improving current crowding, distributing current more uniformly, increasing current density, and fully utilizing the material of said active layer.

8. The light emitting diode (LED) assembly emitting light of mixing colors of claim 7,
wherein said patterned second electrode is a ring-grid-shape.

9. The light emitting diode (LED) assembly emitting light of mixing colors of claim 7,
wherein said patterned second electrode is a multi-ring-plus-shape.

10. The light emitting diode (LED) assembly emitting light of mixing colors of claim 1,
wherein a material system of said first active layer comprises elements selected from a group comprising Al, As, B, Bi, Ga, In, N, and P.

11. The light emitting diode (LED) assembly emitting light of mixing colors of claim 1,
wherein a material system of said first active layer is selected from a group comprising AlGaInP, InGaN, GaInNP, GaNP, GaAsP, AlGaAs, AlGaP, InGaP, and GaP:N.

12. The light emitting diode (LED) assembly emitting light of mixing colors of claim 1,
wherein a material system of said second active layer comprises elements selected from a group comprising Al, Be, Cd, Ga, In, N, S, Se, Te, and Zn.

13. The light emitting diode (LED) assembly emitting light of mixing colors of claim 1,
wherein a material system of said second active layer is selected from a group comprising GaInN, AlGaInN, GaN, BeZnCdSe, BeZnCdTe, ZnSe, ZnCdSe, ZnSeTe, SiC(6H), and ZnSSe.

14. A light emitting diode (LED) assembly emitting light of mixing colors, comprising:
a first epitaxial layer comprising a first cladding layer and a first active layer emitting light of first wavelength;
a second epitaxial layer comprising a second cladding layer and a second active layer emitting light of second wavelength;
wherein said first active layer bonding to said second active layer;
a second electrode for wire bonding disposed on said second cladding layer; and
a submount that is electrically conductive;
wherein one side of said submount bonded to said first cladding layer.

15. The light emitting diode (LED) assembly emitting light of mixing colors of claim 14,
further comprising a first electrode disposed on the other side of said submount.

16. The light emitting diode (LED) assembly emitting light of mixing colors of claim 15,
wherein said first electrode has the opposite polarity to that of said second electrode so that said first epitaxial layer and said second epitaxial layer are electrically connected in serial.

17. The light emitting diode (LED) assembly emitting light of mixing colors of claim 16,
further comprises a multiple quantum barrier-well (MQBW) layer sandwiched between said first active layer and said second active layer.

18. The light emitting diode (LED) assembly emitting light of mixing colors of claim 15,
further comprises a third electrode; wherein said first electrode having the same polarity as that of said second electrode; and wherein said third electrode having an opposite polarity to that of said first and said second electrodes so that said first epitaxial layer and said second epitaxial layer are electrically controlled separately.

19. The light emitting diode (LED) assembly emitting light of mixing colors of claim 18,
further comprises two MQBW layers; wherein one of said MQBW layers sandwiched between said third electrode and said first epitaxial layer and the other of said MQBW layers sandwiched between said third electrode and said second epitaxial layer.

20. The light emitting diode (LED) assembly emitting light of mixing colors of claim 14,
further comprises a reflector/Ohmic layer sandwiched between said submount and said first epitaxial layer.

21. The light emitting diode (LED) assembly emitting light of mixing colors of claim 20,
wherein said reflector/Ohmic layer comprises materials selected from a group comprising metals of Al, Au, Ag, In, Ni, Ti, Pd, Pt, and alloys of said metals.

22. The light emitting diode (LED) assembly emitting light of mixing colors of claim 14,
wherein said second electrode for wire bonding is patterned for improving current crowding, distributing current more uniformly, increasing current density, and fully utilizing the material of said active layer.

23. The light emitting diode (LED) assembly emitting light of mixing colors of claim 22,
wherein said patterned second electrode is a ring-grid-shape.

24. The light emitting diode (LED) assembly emitting light of mixing colors of claim 22,
wherein said patterned second electrode is a multi-ring-plus-shape.

25. The light emitting diode (LED) assembly emitting light of mixing colors of claim 14,
wherein a material system of said first active layer comprises elements selected from a group comprising Al, As, B, Bi, Ga, In, N, and P.

26. The light emitting diode (LED) assembly emitting light of mixing colors of claim 14,
wherein a material system of said first active layer is selected from a group comprising AlGaInP, InGaN, GaInNP, GaNP, GaAsP, AlGaAs, AlGaP, InGaP, and GaP:N.

27. The light emitting diode (LED) assembly emitting light of mixing colors of claim 1,
wherein a material system of said second active layer comprises elements selected from a group comprising Al, Be, Cd, Ga, In, N, S, Se, Te, and Zn.

28. The light emitting diode (LED) emitting light of mixing colors of claim 1, wherein a material system of said second active layer selected from a group comprising GaInN, AlGaInN, GaN, BeZnCdSe, BeZnCdTe, ZnSe, ZnCdSe, ZnSeTe, SiC(6H), and ZnSSe.

29. A method for manufacturing light emitting diode (LED) assemblies emitting light of mixing colors, comprises the steps:
bonding a first epitaxial layer of a first light emitting diode (LED) wafer emitting light of first wavelength to a second epitaxial layer of a second light emitting diode (LED) wafer emitting light of second wavelength to form a LED assembly wafer;
removing the substrate of said first LED wafer, and said first epitaxial layer exposed;
disposing a reflector/Ohmic layer on exposed said first epitaxial layer;
bonding a submount to said reflector/Ohmic layer;
removing the substrate of said second LED wafer, and said second epitaxial layer exposed;
disposing a second electrode on exposed said second epitaxial layer;
dicing said LED assembly wafer into individual LED assemblies.

30. The method for manufacturing light emitting diode (LED) assemblies emitting light of mixing colors of claim 29, further comprises: a step of disposing a third electrode to either said first epitaxial layer or said second epitaxial layer before bonding said first epitaxial layer to said second epitaxial layer; a step of etching through said second epitaxial layer at a pre-determined area until said third electrode exposed and then disposing an Ohmic contact pad on exposed said third electrode for wire bonding before dicing said LED assembly wafer.

31. A lam for LEDs (including LED assemblies), comprises:
a base for mounting a LED;
a hemisphere-shaped dome formed from a material selected from a group comprising epoxy, glass, and plastics; wherein said material being doped with nano-particles so that the refraction index of said material is the same or similar to that of the material of the top epitaxial layer of said LED; and wherein the diameter of said hemisphere-shaped dome being equal to or larger than the production of said refraction index of said material of said dome and the size of said LED.

32. The lam for LEDs (including LED assemblies) of claim 31, further comprises a reflective cup surrounding said dome for reflecting emitted light of said LED to desired direction.
